(19) United States
(12) Patent Application Publication
(10) Pub. No.: US 2026/0311937 A1
(43) Pub. Date: Oct. 8, 2026

(54) CAPACITIVE RF MICROSWITCH FOR HIGH-POWER APPLICATIONS

(71) Applicant: THALES, MEUDON (FR)

(72) Inventors: José-Paolo MARTINS, PALAISEAU (FR); Matthieu LE BAILLIF, PALAISEAU (FR); Etienne EUSTACHE, PALAISEAU (FR); Shailendra BANSROPUN, PALAISEAU (FR); Afshin ZIAEI, PALAISEAU (FR)

(21) Appl. No.: 19/479,118

(22) PCT Filed: Apr. 25, 2024
(86) PCT No.: PCT/EP2024/061480

§ 371 Date: Oct. 27, 2025

(30) Foreign Application Priority Data
Apr. 27, 2023 (FR) FR2304266

(51) Int. Cl. H01H 1/00; B81B 3/00; H01H 11/00

(52) U.S. Cl. CPC H01H 1/0036; B81B 3/0021; H01H 11/00; B81B 2201/016

(57) ABSTRACT

A capacitive radiofrequency microelectromechanical system includes a metal membrane suspended above an RF transmission line on the surface of a substrate, wherein the metal membrane includes: a lower element having a first part located partially above the electrodes, which are covered by elements made of a first dielectric material, and partially above the RF line, which is covered by an element made of a second dielectric material; an upper element located above the first part of the lower element; the activation electrodes being arranged on either side of the RF transmission line; the ground planes being arranged on either side of the RF line and along axes parallel to the first axis X; the membrane having flexible areas consisting of some of the second parts of the lower element and a rigid area consisting of the stack of the first part of the lower element and the upper element.

### CROSS-REFERENCE TO RELATED APPLICATIONS

This application is a National Stage of International patent application PCT/EP2024/061480, filed on Apr. 25, 2024, which claims priority to foreign French patent application No. FR 2304266, filed on Apr. 27, 2023, the disclosures of which are incorporated by reference in their entireties.

### FIELD OF THE INVENTION

The field of the invention is that of high-power capacitive RF microswitches (of powers typically greater than 30 W) produced using microelectromechanical system (MEMS) technology.

### BACKGROUND

The challenge is that of designing RF MEMS switches capable of withstanding high power levels (>30 W) while at the same time guaranteeing high reliability levels (ideally >>10¹¹ cycles). For this purpose, it is therefore necessary to design membranes the mechanical properties of which make it possible to withstand high powers, while at the same time applying relatively moderate actuation voltages (ideally s 50 V). It is also necessary to relax the (DC and RF) electrical stresses on the dielectric material of the activation electrodes, so as to significantly increase the reliability of the component. The present invention aims to address these problems by proposing an original architecture.

Generally speaking, RF MEMS switches consist of a metal membrane that, under the effect of external (electrical, magnetic, thermal, etc.) loading, will position itself on an RF signal line. Stepan Lucyszun presents the main RF MEMS configurations in “Advanced RF MEMS”, Cambridge University Press, 2010.

There are two MEMS switch configurations that may be actuated differently:
ohmic RF MEMS switches, in which the metal membrane makes direct contact with the RF metal line. In that case, there is metal-to-metal contact, like the configuration presented by Deepak Bansal et al. “Improved Design of Ohmic RF MEMS Switch for Reduced Fabrication Steps”, IEEE Transactions on Electron Devices, 2019. (Figures (5a) and (5b) of that publication show two RF MEMS switch configurations: ohmic (5a) and capacitive (5b)).

The performance of this type of RF component is related directly to the capacitance value when the membrane is in the high state and to the contact resistance value when the membrane is in the low state. This configuration has the advantage of being able to address low frequency bands (from DC to a few GHz). However, the powers that these devices are able to withstand remain linked to the choice of metal materials. These have to withstand the currents (resulting from the RF power in the metallizations) without experiencing degradation (micro-welding, migration, increase in contact resistance with degradation of ohmic contact quality, etc.). The power withstand of these devices is therefore limited as soon as the operating frequency exceeds a few GHz.

With regard to capacitive RF MEMS switches, the movable metal membrane makes contact with the RF metal signal line via a dielectric material that will provide electrical isolation. This is a capacitive contact the properties of which define the RF performance of the component and that is related to the ratio of capacitance when the membrane is in the low state to capacitance when the membrane is in the high state. The higher the ratio between these capacitances, the greater the distinction between the two states, thus making it easier to design these devices for better RF performance, as described by Hao Wei et al., “High on/off capacitance ratio RF MEMS capacitive switches”, Journal of Micromechanics and Microengineering, 2017.

Sudhanshu Shekhar (Sudhanshu Shekhar et al., “Thermally robust thin-metal membrane capacitive RF MEMS switch”, Journal of Micro and Smart Systems, 2019) presents one example of a capacitive RF MEMS switch with silicon nitride as dielectric material and the schematic principle of which is shown in FIG. 1a (ohmic switch configuration) and FIG. 1b (capacitive switch configuration). The latter type of device is generally more suitable for higher frequency bands (>a few GHz) than ohmic RF MEMS. However, the main advantage of these devices, compared to the ohmic RF MEMS, is their better RF power withstand at higher frequencies, due to the presence of the dielectric material, which will limit the flow of current.

The author LI-YA MA (LI-YA M A et al., “Comprehensive Study on RF-MEMS Switches Used for 5G Scenario”, IEEE Access, 2019) presents detailed prior art with regard to RF MEMS switches, whether in an “ohmic” configuration or in a “capacitive” configuration. This study presents a wide variety of switches originating from different technologies and architectures for various performance (frequency band, S parameters, switching time, reliability, power withstand, etc.).

In this context, the applicant proposes a novel original architecture capable of withstanding high RF powers while at the same time guaranteeing the reliability of the component.

The applicant has already developed a capacitive RF MEMS switch capable of withstanding powers greater than 20 W, and described notably by A. Ziaei et al., “Fast high power capacitive RF-MEMS switch for X-Band applications”, European Solid State Device Research Conference, 2015 (FIG. 2 of that article).

The architecture of this component described in that article has limitations, in terms of power withstand, which are defined mainly by the rigidity of the membrane (self-activation level under the effect of incident RF power) and by the strength of the dielectric material, which has to withstand the incident power and also the voltage needed to switch the membrane to the low state. The more it is sought to achieve high power levels, the more rigid the metal membrane has to be and the more it is necessary to apply a high voltage to switch the membrane.

FIG. 2 illustrates a scanning electron microscope (SEM) image of a capacitive RF MEMS switch, in a coplanar architecture, produced by the applicant for RF power applications.

FIGS. 3a and 3b illustrate this type of “parallel” capacitive RF MEMS switch configuration using coplanar technology (CPW) and relate, respectively, to a 3D view and a sectional view highlighting the ground planes, the RF line, the air gap between the membrane and the dielectric-covered RF line. More precisely, FIG. 3a shows, on a substrate 10, the ground planes 13a and 13b, on which a membrane 14 rests, and over-metallizations 15a and 15b rest on the RF line. FIG. 3b illustrates the RF line 11, covered with a dielectric 12.

Table 1 below shows prior art indexing the features of power RF MEMS switches developed by the applicant, power RF MEMS switches stemming from academic research, and those from component suppliers. These components exhibit power withstands of less than or equal to 25 W for a number of switching operations not exceeding 3.10 cycles. It should be noted that the number of cycling switching operations decreases as the power level increases. For capacitive RF MEMS switches, this number of switching operations decreases drastically with the voltage applied, and seen by the dielectric material, to switch the membrane to the low state. C. Goldsmith (C. Goldsmith et al., “Lifetime characterization of capacitive RF MEMS switches”, IEEE MTT-S International Microwave Symposium, 2001) was able to demonstrate that the number of switching operations on capacitive RF MEMS decreases by the order of one decade each time the actuation voltage is increased by 5-7 V:

TABLE 1

| | Parameters | | | |
|---|---|---|---|---|
| | Values | | | |
| | Type | | | |
| | Capacitive | Ohmic | Ohmic | Capacitive |
| | Architecture | | | |
| | Parallel/series | Series | Series | Parallel |
| Frequency band | [8-12] GHz | DC - 3 GHz | DC - 11(14) GHz | [8-12] GHz |
| Isolation (dB) | >25 (SPST) | >25 (SPST) | 19 at 6 GHz (SP4T) | 24 (SPST) |
| | >35 (SPDT) | | | |
| Insertion losses | <0.35 (SPDT) | <0.3 (SPST) | 0.4 at 6 GHz (SP4T) | 0.2 (SPST) |
| (dB) | <0.6 (SPDT) | | | |
| Power withstand | 25 (Cold | 25 CW (Cold | 5 (Cold | 12 (Hot |
| (W) | switching) | switching) | switching) | switching) |
| Actuation | 40 | 80 | 80 | 65 |
| voltage (V) | | | | |
| Switching time | 4 μs | 10 μs | 30 μs | 20 |
| Number of | 10⁹ at 20 | 3.10⁹ | 10⁹ | 10⁴ at |
| switching | W/2 kHz | | | 1-12 W |
| operations | | | | |
| Manufacturers | THALES | MENLOMICRO | Analog | University of |
| | | | Devices | California |

With the following references: https://menlomicro.com and https://www.analog.com and University of California (Hyun-Ho Yang et al., “A High Power Stress-Gradient Resilient RF MEMS Capacitive Switch”, Journal of Microelectromechanical Systems, 2014).

A number of authors present examples of capacitive RF MEMS switch architectures comprising remote activation electrodes (covered with a dielectric), between the central RF line and the remote ground planes (Hao Wei et al, “High on/off capacitance ratio RF MEMS capacitive switches”, Journal of Micromechanics and Microengineering, 2017, K. Srinivasa Rao et al., “Fabrication and Characterization of Capacitive RF MEMS Perforated Switch”, IEEE Access, 2018). FIG. 4a (schematic principle) and FIG. 4b (optical microscope image of the component) show for example the architecture proposed by Hao Wei. The purpose of this architecture configuration is to release the stresses on the dielectric of the RF line. For this purpose, a voltage is applied between the activation electrodes and the membrane connected to the ground planes. The membrane is then lowered onto a metallization that has been deposited beforehand on the dielectric material of the RF transmission line. By virtue of this architecture, the dielectric of the central line is no longer subject to an activation DC voltage, and simple contact of the membrane on the metal above this same dielectric makes it possible to recover very good capacitive contact.

However, this approach has certain limits. First of all, in a coplanar waveguide (CPW) configuration, for matching reasons, the width of the RF line and the distance between this same line and the ground planes depends on the properties of the substrate (thickness, tan δ, εᵣ) on which the component is produced. This means that, for a given substrate, these dimensions are fixed in order to be matched to 50Ω, and therefore the space (between the central line and the ground planes) to produce activation electrodes is limited. This becomes more problematic when seeking to address high RF power levels while at the same time maintaining moderate switching voltages. For high power levels, it is necessary to increase the air gap and/or the stiffness of the membrane in order to push back the self-activation level of the component under the effect of the electromagnetic field. In the case of the architecture presented by Hao Wei, it would be necessary to significantly increase the size of the electrodes so that the electrostatic force applied to the membrane is greater, while at the same time maintaining moderate activation voltages. It is necessary to add to this the influence of the activation lines passing between the RF line and the ground planes (FIG. 4b). These metal lines cause signal losses (through electromagnetic coupling), with degradation of insertion losses (S₂₁). The S parameter results, on this architecture, show isolations in accordance with the simulations, while a discrepancy is observed on insertion losses between the measurement and the simulations. In addition, reliability problems related to the injection of charges into the dielectric are observed on the activation electrodes, without otherwise improving the reliability of the component.

The use of remote electrodes for capacitive RF MEMS is an already proven methodology for reducing stress on the dielectric material. However, this solution means, for power withstand requirements, having to have enough space between the RF line and the ground planes to insert, into said space, electrodes that are large enough to apply an electrostatic force that is able to compensate for the stiffness of the membrane. It will be recalled that this stiffness, along with the air gap, defines the power withstand of the component. The more it is sought to achieve high power levels, the larger the electrodes have to be in order to actuate the device with reasonable voltages.

In this context, the applicant proposes a solution comprising the use of a membrane, composed of a rigid part and a flexible part, allowing the activation electrodes to be transferred to the ground planes, thus providing flexibility with regard to the size of the activation electrodes. Moreover, these are no longer located between the RF line and the ground plane, thus avoiding electromagnetic coupling, which may cause RF losses. This approach makes it possible to keep components compact, even for high power levels, while at the same time limiting impact on the overall architecture. The flexible part, along with the size of the activation electrodes with the part of the rigid membrane opposite, are able to be adjusted to the required power level, while at the same time guaranteeing moderate actuation voltages.

### SUMMARY OF THE INVENTION

More precisely, the present invention relates to a capacitive radiofrequency microelectromechanical system comprising a metal membrane suspended above an RF transmission line arranged along a first axis X on the surface of a substrate, activation electrodes and ground planes on which said membrane rests, characterized in that:
said metal membrane comprises:
   a lower element having a first part located partially above said electrodes, which are covered by elements comprising at least one first dielectric material, and partially above said RF line, which is covered by an element made of a second material, said lower element having second parts located partially in contact with said ground planes;
   an upper element located above said first part of the lower element;
the activation electrodes being arranged on either side of the RF transmission line;
said ground planes being arranged on either side of the RF line and along axes parallel to said first axis X;
said membrane comprising flexible areas consisting of some of the second parts of the lower element and a rigid area consisting of the stack of the first part of the lower element and the upper element.

According to some variants of the invention, said elements comprising at least one first dielectric material are structured and have structuring patterns, of dimensions between 50 nanometers and 5 micrometers.

It should be noted that the existing solutions regarding remote electrodes only transfer the failure of capacitive RF MEMS from the dielectric of the central line to the dielectric on the activation electrodes. The introduction of microstructuring/nanostructuring of the dielectric on the activation electrodes makes it possible to limit the injection of charge into this material by drastically minimizing the surface area in contact between this dielectric and the membrane when the latter is in the low state. The limitation of the actuation voltages, by virtue of this type of architecture, and the structuring of the dielectric of the activation electrodes thus makes it possible to improve the reliability of this type of component, even for high power levels (>30 W).

According to some variants of the invention, the first dielectric material has a strength greater than or equal to 5 MV/cm, and is for example made of SiO₂ or SiN or Al₂O₃.

According to some variants of the invention, the element made of a second dielectric material is covered with an upper metal element.

According to some variants of the invention, the total thickness of an activation electrode and of an element made of a first dielectric material is equal to the total thickness of the thickness of the part of said RF line under the membrane and of an element made of a second dielectric material.

According to some variants of the invention, the thickness of the lower element of the membrane is between 500 nanometers and 2 micrometers.

According to some variants of the invention, the thickness of the upper element of said membrane is greater than 2 micrometers.

According to some variants of the invention, the upper element of said membrane is structured, said structure being for example in the form of a lattice and having patterns of dimensions greater than 1 micrometer.

According to some variants of the invention, the second dielectric material has a dielectric constant ε₀ greater than that of silicon oxide, said second dielectric material being for example HfO₂ or ZrO₂ or Y₂O₃ or Al₂O₃ or SiN.

According to some variants of the invention, the lower element of the membrane is made of multilayers based on one or more refractory materials, for example W, Mo, Ta, TaN, TiN, TiW and one or more conductive materials, for example Au, Al, Cu, the upper element of the membrane being made of conductive material, for example Au or Cu.

The invention also relates to a method for fabricating a capacitive radiofrequency microelectromechanical system according to the invention, comprising:
a step of producing activation electrodes on the surface of a substrate;
a step of producing elements made of at least one first dielectric material on the surface of some of said activation electrodes;
a step of producing the RF line located between said activation electrodes;
a step of producing an element made of a second dielectric material above part of the RF line;
a step of producing said ground planes on either side of said RF line;
a step of producing the lower element of said membrane;
a step of producing the upper element of said membrane.

According to some variants of the method of the invention, the step of producing the activation electrodes on the surface of a substrate is carried out by sputtering or by evaporation.

According to some variants of the method of the invention, the lower element of the membrane is produced by multilayer depositions comprising at least one metal layer made of Au or Al or Cu and at least one other metal layer, for example made of refractory material, said depositions being carried out by sputtering and/or evaporation.

According to some variants of the method of the invention, the upper element of said membrane is produced by electrolytic deposition.

According to some variants of the method of the invention, the element made of a second dielectric material on the surface of said RF line is produced by physical vapor deposition (PVD) or by chemical vapor deposition (CVD) or by atomic layer deposition (ALD) of atomic thin films with thicknesses for example between 20 nanometers and 300 nanometers.

According to some variants of the method of the invention, said method comprises carrying out a step of partially thickening said RF line in regions located at the periphery of said membrane.

According to some variants of the method of the invention, the step of partially thickening said RF line and the step of producing said ground planes are carried out in one and the same metal deposition step.

According to some variants of the method of the invention, the production of the ground planes or the production of the ground planes and the step of partially thickening said RF line are carried out by electrolytic growth.

According to some variants of the method of the invention, the structuring patterns of said elements made of at least one first dielectric material and present above said electrodes are produced by etching a first dielectric material or by localized deposition of a dielectric material on a first dielectric material.

### BRIEF DESCRIPTION OF THE DRAWINGS

The invention will be better understood and other advantages will become apparent on reading the following non-limiting description with reference to the appended figures, in which:

FIG. 1a illustrates the principle of an ohmic RF MEMS switch;

FIG. 1b illustrates the principle of a capacitive RF MEMS switch;

FIG. 2 illustrates a scanning electron microscope (SEM) image of a capacitive RF MEMS switch, in a coplanar architecture, produced by the applicant for RF power applications;

FIG. 3a illustrates a 3D view of a capacitive RF MEMS switch in a “parallel” configuration according to the known prior art;

FIG. 3b illustrates a sectional view with a metal membrane (connected to the ground plane) above (separated by an air gap from) an RF transmission line covered by a dielectric according to the known prior art;

FIG. 4a illustrates the schematic principle of a capacitive RF MEMS RF switch architecture in a “CPW” architecture with remote activation electrodes according to the known prior art;

FIG. 4b illustrates a microscope image of the component illustrated in FIG. 4a;

FIG. 5a illustrates a 3D view of a component according to the invention;

FIG. 5b illustrates a plan view of a component of the invention;

FIG. 6 illustrates the evolution of strength as a function of dielectric constant for various materials;

FIG. 7a illustrates the accumulation of charges in a planar dielectric material when the membrane is in the low state in a component of the invention;

FIG. 7b illustrates the accumulation of charges in a structured dielectric material when the membrane is in the low state in a component of the invention;

FIG. 8a illustrates a configuration according to the invention, without metal on the dielectric covering the RF line, with application of electrostatic fields E_{ch} to the activation electrodes and E′_{ch} to the RF line, in the high state, in a component of the invention;

FIG. 8b illustrates a configuration according to the invention, without metal on the dielectric covering the RF line, with application of electrostatic fields E_{ch} to the activation electrodes and E′_{ch} to the RF line, in the low state, in a component of the invention;

FIG. 8c illustrates a configuration according to the invention, with metal on the dielectric covering the RF line, with application of electrostatic fields E_{ch} to the activation electrodes and E′_{ch} to the RF line, in the high state, in a component of the invention;

FIG. 8d illustrates a configuration according to the invention, with metal on the dielectric covering the RF line, with application of electrostatic fields E_{ch} to the activation electrodes and E′_{ch} to the RF line, in the low state, in a component of the invention;

FIG. 9 illustrates one example of electrolytic growth of gold of a few micrometers, in the form of a lattice, to reinforce the rigidity of the membrane in a configuration of the invention;

FIG. 10a illustrates the flexible areas of the membrane of a component of the invention;

FIG. 10b illustrates the rigid area of the membrane of a component of the invention;

FIG. 11 illustrates the geometrical parameters of the RF MEMS component architecture according to the invention;

FIG. 12a illustrates an optical microscope image of a component according to the invention;

FIG. 12b illustrates a 3D optical profilometer view of a component according to the invention;

FIG. 13a illustrates an optical profilometer acquisition of a first RF MEMS switch fabrication according to the invention with a first flexible area length;

FIG. 13b illustrates an optical profilometer acquisition of a first RF MEMS switch fabrication according to the invention with a second flexible area length;

FIG. 13c illustrates an optical profilometer acquisition of a first RF MEMS switch fabrication according to the invention with a third flexible area length;

FIG. 14a illustrates an optical profilometer acquisition in the high state of an RF MEMS switch according to the invention;

FIG. 14b illustrates an optical profilometer acquisition in the low state of an RF MEMS switch according to the invention;

FIG. 15 illustrates the S parameters of a component according to the invention and the comparison with those of an architecture from the known prior art;

FIG. 16 illustrates a plan view of a component according to the invention and sectioning axes A and B;

FIG. 17a illustrates a view along section A in the high position of the component illustrated in FIG. 16;

FIG. 17b illustrates a view along section A in the low position of the component illustrated in FIG. 16;

FIG. 18a illustrates a view along section B in the high position of the component illustrated in FIG. 16;

FIG. 18b illustrates a view along section B in the low position of the component illustrated in FIG. 16;

FIG. 19a illustrates a first step of the method for producing one example of a component according to the invention;

FIG. 19b illustrates a second step of the method for producing one example of a component according to the invention;

FIG. 19c illustrates a third step of the method for producing one example of a component according to the invention;

FIG. 19d illustrates a fourth step of the method for producing one example of a component according to the invention;

FIG. 19e illustrates a fifth step of the method for producing one example of a component according to the invention;

FIG. 19f illustrates a sixth step of the method for producing one example of a component according to the invention;

FIG. 19g illustrates a seventh step of the method for producing one example of a component according to the invention;

FIG. 19h illustrates an eighth step of the method for producing one example of a component according to the invention.

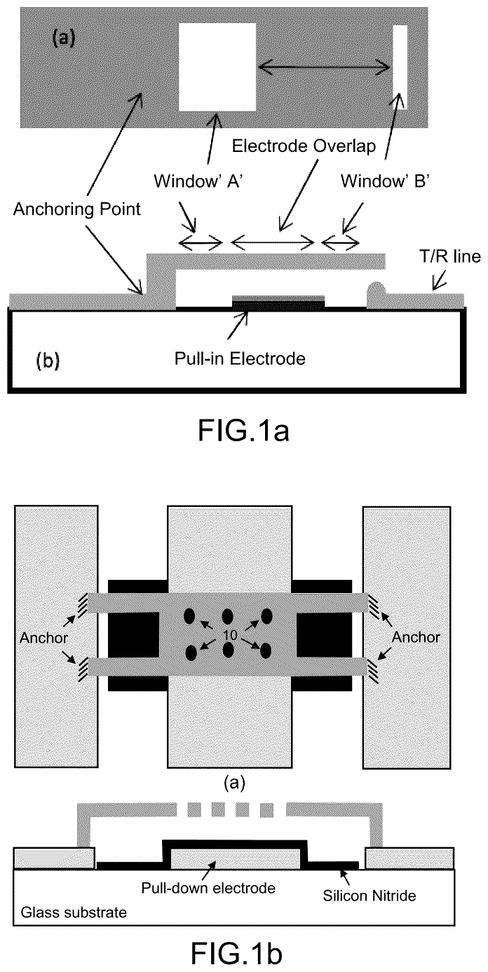

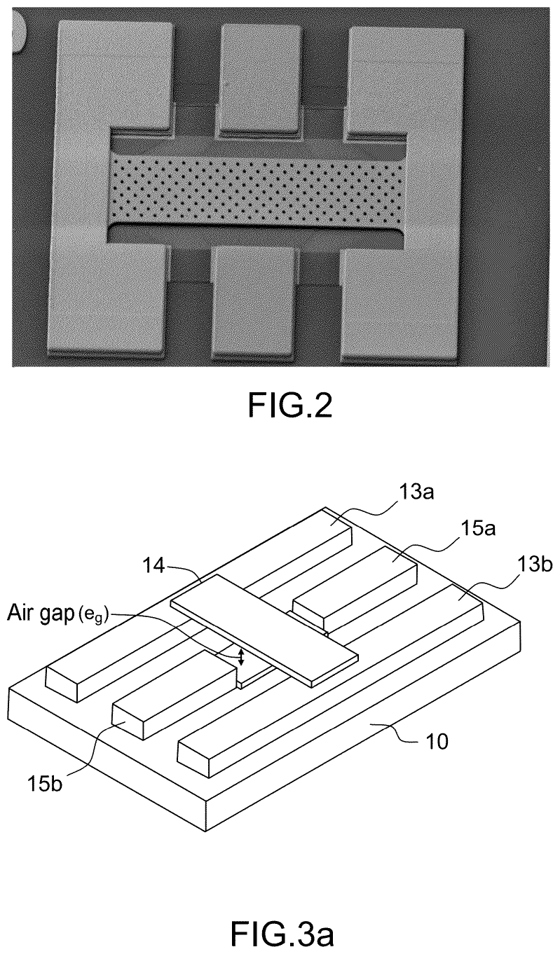

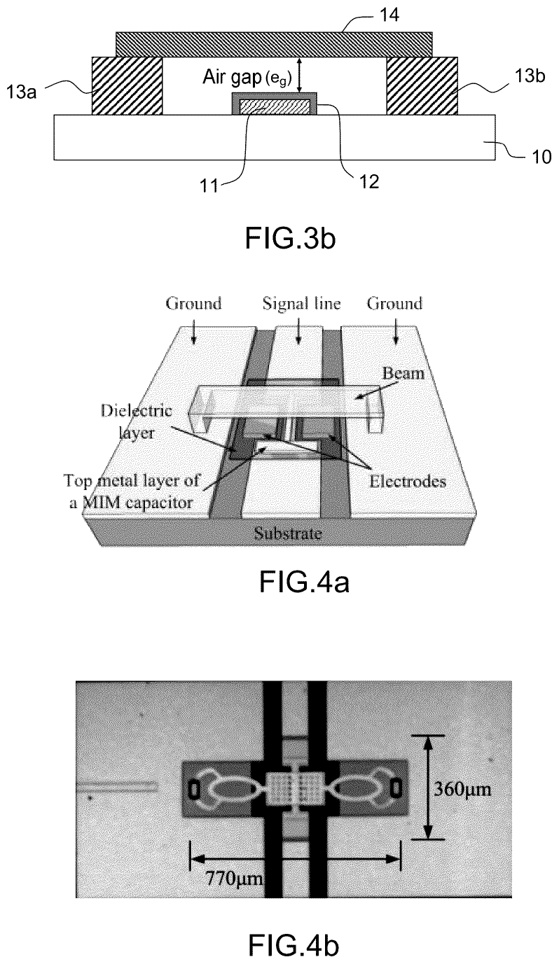

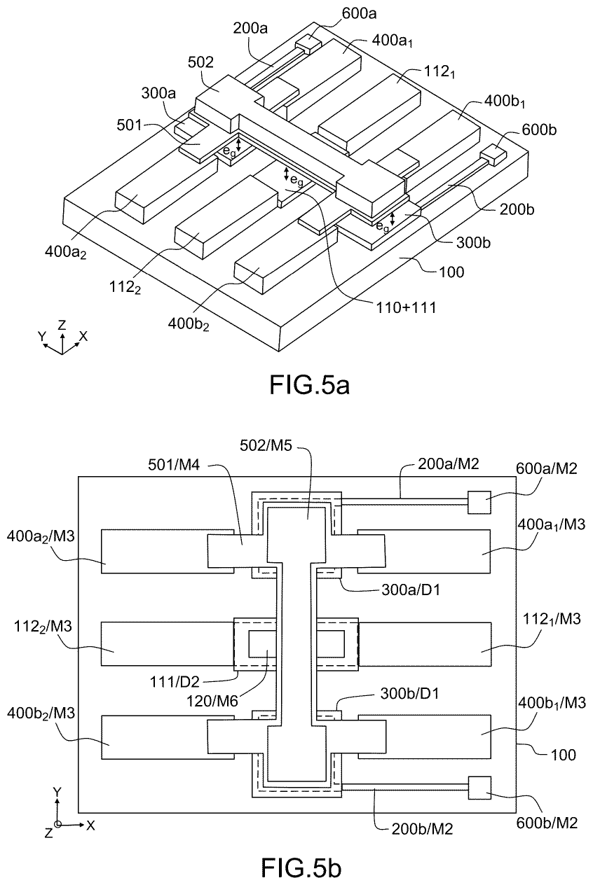

### DETAILED DESCRIPTION

Generally speaking, the novel capacitive RF MEMS switch architecture according to the invention makes it possible to address the needs in terms of high power and increased reliability. For this purpose, this novel architecture proposes the following features, having notably the advantages described in more detail below:
dissociation of the RF part and the DC part (for activation) so as to minimize stress on the dielectric of the RF line. The activation electrodes are remote so as to provide for their dimensioning, thus making it possible to target very high RF powers (>>30 W). These activation electrodes are located at the ground planes, imparting flexibility with regard to their dimensioning so as to target high power levels while at the same time guaranteeing moderate actuation voltages;
a first dielectric material, with a high dielectric strength and deposited on the activation electrodes, may advantageously, according to some variants of the invention, be microstructured/nanostructured in order to improve the reliability of the component by limiting the injection of charges during switching operations by virtue of a small surface area in contact with the membrane;
a second dielectric material deposited on the RF transmission line provides the component with its RF properties (power withstand and S parameters) when the membrane is in the low state. By virtue of the proposed architecture, the stresses on this material are minimized, making it possible to reduce the thickness thereof and/or to use a material with a high dielectric constant the properties of which (depending on the thickness) are not usually compatible with capacitive RF MEMS because these materials generally do not withstand the voltages applied for actuation;
a membrane composed of a flexible part so as to allow it to move and a rigid part thick enough to maintain a structural rigidity makes it possible to limit its deformation (keep the membrane straight) under various types of loading (RF power and actuation) and able to withstand high RF powers.

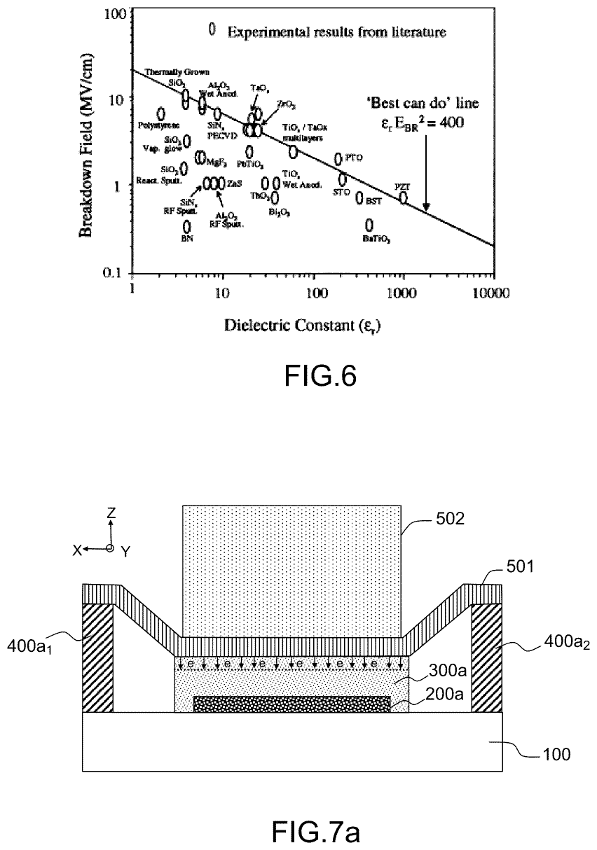

Generally speaking, according to the present invention, it is proposed to transfer the activation electrodes to the ground planes. Said ground planes are suspended, locally, above the activation electrodes, these two elements being separated by an air gap (e₉). FIG. 5a illustrates a 3D view and FIG. 5b illustrates a plan view of one example of a component according to the present invention. Activation electrodes 200a and 200b, extended by connection pads 600a and 600b, covered with elements 300a and 300b made of a first dielectric material D1 (elements 300a/D1 and 300b/D1 shown in FIG. 5b), are thus produced on a substrate 100. Ground planes 400a1, 400b1, 400a2 and 400b2 are distributed on either side of the membrane having a lower element 501 that rests on said ground planes, this lower element 501 being locally covered with an upper element 502. The RF line 110 is locally covered with an element 111 made of a second dielectric material D2. According to one variant illustrated in FIG. 5b, the element 111 may itself be covered with a metallization 120 made of metal M6 (this constituting one variant of the component illustrated in FIG. 5a). The RF line is also thickened at its periphery by metallizations 112₁ and 112₂.

The ground planes 400a₁, 400b₁, 400a₂ and 400b₂ and the metallizations 112₁ and 112₂ may advantageously be made of one and the same metal, referenced M3. The lower element 501 of the membrane is made of a metal referenced M4, the upper element 502 of the membrane being made of a metal referenced M5.

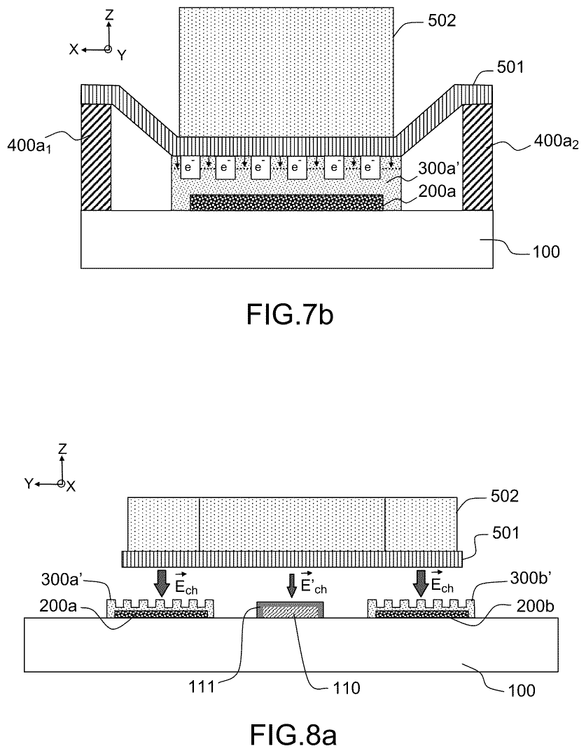

The movable metal membrane is suspended and separated by an air gap (e_{g}) from the two activation electrodes made of metal M2 and from the thin RF line 100 made of metal M1 (not shown because it is covered by the element 111 made of dielectric D2). The first dielectric material, referenced D1 (located above the electrodes), is chosen for its good voltage withstand (high dielectric strength and thickness). For example, first dielectric materials such as silicon nitride (SiN), silicon oxide (SiO₂), aluminum oxide (Al₂O₃), polymers, etc., deposited using various techniques (LPCVD, PECVD, PVD, CVD, ALD, etc.), may have dielectric strengths greater than 6 MV/cm, as illustrated in FIG. 6, which shows the evolution of strengths as a function of dielectric constant in accordance with the reference: Pushkar Jain et al., “Embedded Thin Film Capacitors—Theoretical Limits”, IEEE Transactions on Advanced Packaging, 2002.

It should be noted that, for the choice of this first dielectric material D1, the value of the dielectric constant is a parameter that is not relevant for the RF performance of the component. In order to withstand high voltages, the thickness of this material is calculated according to its dielectric strength. For example, Al₂O₃ deposited by plasma-assisted ALD may have a dielectric strength of 10 MV/cm. To withstand a voltage of 200 V, the necessary thickness of Al₂O₃ is of the order of 200 nm. Generally speaking, the minimum thickness of this dielectric must be sufficient to withstand the voltage imposed to switch the membrane to the low state. By applying a sufficient voltage between the activation electrodes and the ground plane/membrane, the membrane will change from a high state to a low state.

Failures due to the charge of the dielectric during the various activations will relate to the first dielectric material D1. Depending on the material used and the mode of actuation (applied voltage and actuation frequency), the first dielectric material D1 charges to a greater or lesser extent, which may cause failure of the component either through a shift in the actuation voltage or by the membrane sticking to the dielectric, as described in the following references: David Mardivirin et al., “Evidence of Successive Fowler-Nordheim and Frenkel-Poole Conductions in Si3N4 Based RF-MEMS Capacitive Switches”, Proceedings of the 40th European Microwave Conference, 2010, Negar Tavassolian et al., “Dielectric Charging in Capacitive RF MEMS Switches: The Effect of Extended Durations of Electric Stress”, IEEE Microwave and Wireless Components Letters, 2011, S. Mellé et al., “Modeling of the dielectric charging kinetic for capacitive RF-MEMS”, IEEE MTT-S International Microwave Symposium Digest, 2005, Anne-Charlotte Amiaud et al., “Modeling tool for capacitive RF MEMS operating bias voltage optimization”, IEEE Transactions on Devices and Materials Reliability, 2019, W. A. de Groot et al., “Review of device and reliability physics of dielectrics in electrostatically driven MEMS devices,” IEEE Transactions on Devices and Materials. Reliability, 2009, W. M. van Spengen, “Capacitive RF MEMS switch dielectric charging and reliability: A critical review with recommendations,” Journal of Micromechanics and Microengineering, 2012.

The first dielectric material D1, at the activation electrodes, acts as an insulator when the membrane is in the low state. In the context of the present invention, the dielectric constant for this first dielectric material D1 is a parameter to be considered only for the RF performance of the device. The material D1 is essential for withstanding the actuation voltages needed to switch the device (depending on the defined power withstand), and is therefore subject to the same failure rules as those cited above. These failures are all the more pronounced when the material D1 is subjected to loading (applied voltage, time spent in the low state, actuation frequency, etc.), as described in: R. W. Herfst et al., “Time and voltage dependence of dielectric charging in RF MEMS capacitive switches”, IEEE International Reliability Physics Symposium Proceedings, 2007.

When a potential difference is applied between the membrane (0 V) and the activation electrodes (+V), this generates an electrostatic force that attracts the (movable) membrane to the material D1. During this contact, a transfer of charges (electrons e⁻) takes place from the membrane to the material D1. These charges then accumulate at the defects in the material D1 so as to be trapped there, as the switching operations progress. This injection of charges into the dielectric material D1 depends on multiple factors such as applied electrostatic field, contact surface area, temperature, etc. This accumulation of charges in the dielectric material D1 generates a “parasitic” electric field that opposes the electric field resulting from the actuation and induces a drift in the actuation voltage (R. W. Herfst et al., “Characterisation of dielectric charging in RF MEMS capacitive switches”, IEEE International Conference on Microelectronic Test Structures, 2006), or even permanent sticking of the membrane to the dielectric D1 (https://menlomicro.com and https://www.analog.com).

Depending on the dielectric material D1 used (T. Lisec et al., “Dielectric Material Impact on Capacitive RF MEMS Reliability”, 34th European Microwave Conference, 2004), and on the electrical stress applied thereto, charge accumulation is localized in the dielectric material over a certain depth (A. Ziaei et al., “Fast high power capacitive RF-MEMS switch for X-Band applications”, European Solid State Device Research Conference, 2015).

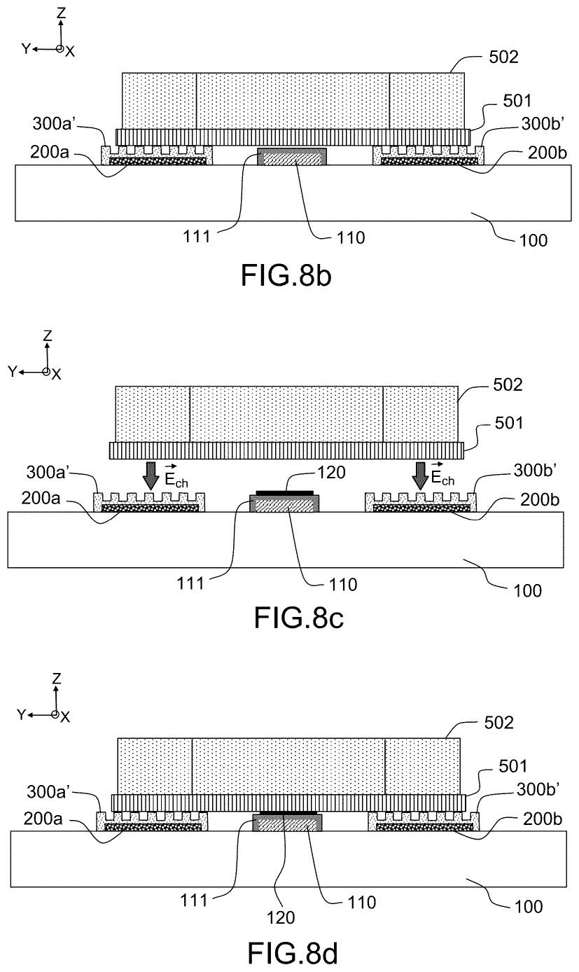

In order to limit the injection of charges into the dielectric material D1, it may be particularly beneficial to drastically reduce the surface area that will be in contact with the membrane (in the low state) by structuring the material D1. This involves generating structures such as for example pillars, holes, lattices, etc. from a few micrometers to a few hundred nanometers in the dielectric material D1. For the same electrical stress, the amount of charge Q′ accumulated at the microstructures/nanostructures (through transfer of electrons e from the membrane) is smaller than the amount of charge Q for a planar surface (as shown in FIGS. 7a and 7b, which relate, respectively, to configurations with accumulation of charges in a planar dielectric material and in a structured dielectric material, when the membrane is in the low state).

This structuring of the dielectric material D1 means that the contact surface area is thus limited when the membrane is in the low state, and the reliability of the component, linked to charge injection, is therefore improved. This reliability will be higher the lower the density of the structures.

Current technologies make it possible to microstructure/nanostructure insulating materials such as SiN, SiO₂, Al₂O₃, etc. over a depth of several hundred nanometers and for resolutions less than 100 nm. It should be noted that it is possible to carry out localized deposition of an insulating material so as to generate microstructures/nanostructures with the same dimensional specifications on the activation electrodes, which may already be passivated beforehand with another insulator.

The choice of the second dielectric material D2 defines the RF performance (S parameters and power withstand) of the component when the membrane of the RF MEMS switch is in the low state. For this purpose, consideration is given to its dielectric constant and the thickness needed to withstand the voltage corresponding to the power injected when the membrane is in the low state according to the formula U=√(RP), where U is voltage in volts, R is the characteristic impedance of the component (50 ohms for an RF circuit and for the calculation in this table), and P is the power in watts injected into the component. Table 2 below shows, for various power levels, the equivalent voltage liable to be applied to the second dielectric material D2 when the membrane is in the low state.

TABLE 2

| Power | Equivalent voltage |
|---|---|
| (watts) | (volts) |
| 1 | 7.1 |
| 5 | 15.8 |
| 10 | 22.3 |
| 15 | 27.4 |
| 20 | 31.6 |
| 30 | 38.7 |
| 50 | 50 |
| 100 | 70.7 |

The dielectric material D2 is subject only to the stress related to the permitted RF power and, possibly, to a voltage of a few volts (applied between the RF line and the ground plane/membrane) so as to optimize the pressing of the membrane onto the dielectric material D2. Electrostatic force equation 1, below,

$$F = - \frac{{ε}_{0} \times S \times {V}^{2}}{2 \times {z}^{2}} \qquad Equation 1$$

with “S”: the opposing surface area between the membrane and the RF line below, ε₀: permittivity of free space, V: the voltage applied across the terminals of the electrodes and z: the position of the membrane along the axis z (between 0 and e_{g}).

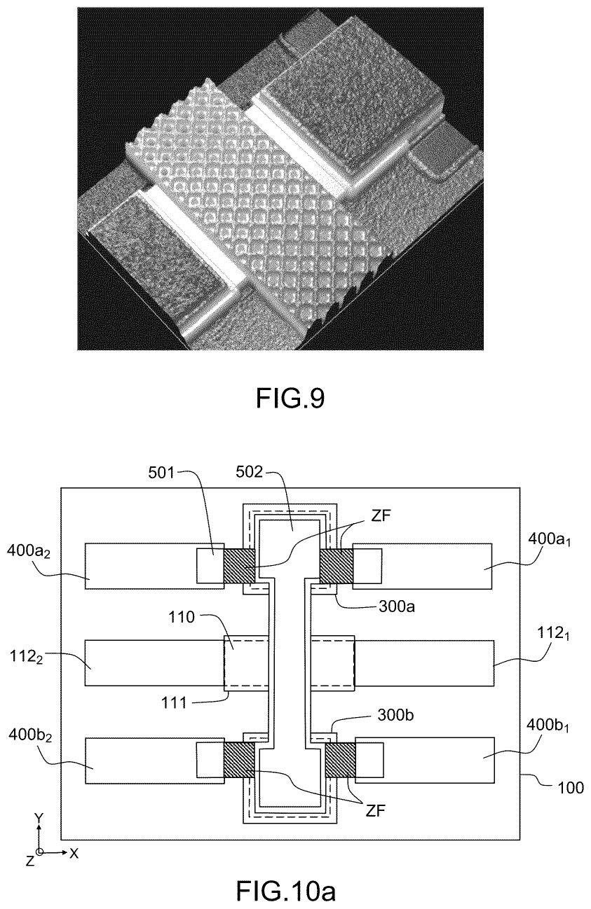

The formula shows that the force F applied to the membrane is proportional to 1/z², where z represents the distance between the membrane and the RF line. This means that this electrostatic force becomes very large when the membrane approaches the RF line covered with the dielectric material D2, even for a low applied voltage. According to one variant of the invention, it is possible to deposit a metal on the dielectric material D2 so that simple contact of the membrane on this metal makes it possible to obtain the desired capacitance, in the low state, and without the membrane needing to be pressed on correctly (the application of a secondary voltage to the RF line is no longer required). FIGS. 8a and 8b show schematic views of the mode of actuation of the capacitive RF MEMS switch without the presence of an additional metal on the dielectric material D2, respectively in the “high state” and in the “low state”, with application of electrostatic fields E_{ch} to the activation electrodes and E′_{ch} to the RF line. FIGS. 8c and 8d show schematic views of the mode of actuation of the capacitive RF MEMS switch with the presence of an additional metal on the dielectric material D2, respectively in the “high state” and in the “low state”, with application of an electrostatic field E_{ch} to the activation electrodes. In this case, the application of an electric field to the RF line is no longer required.

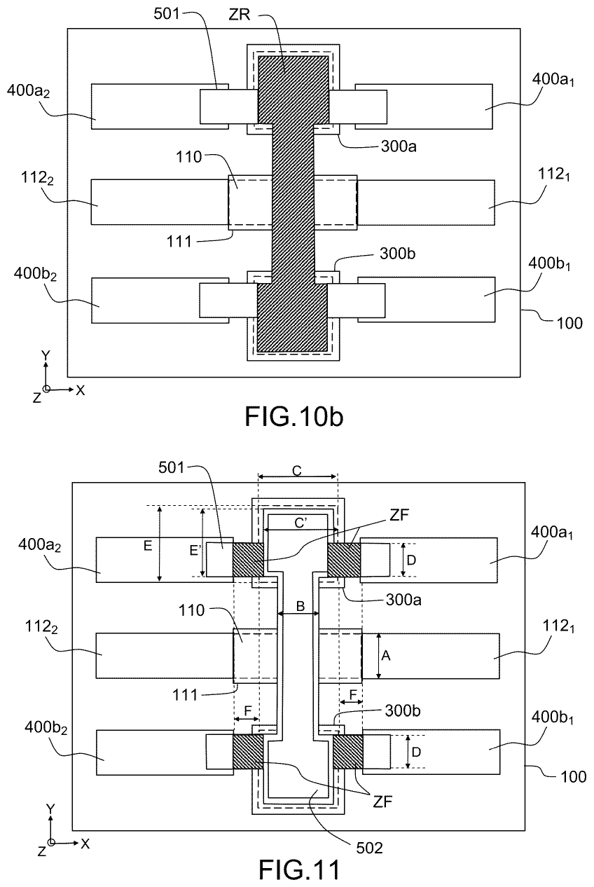

The RF performance of the device, in the low state, is therefore related to the capacitance generated at the dielectric material D2 and the value of which depends on the thickness of the dielectric material D2, on its dielectric constant (at the frequency under consideration), on the contact surface area B*A and on the quality of the contact of the membrane on the dielectric material D2 (which may be ideal by adding a metal M6 to the dielectric material D2). FIG. 9 illustrates one example of electrolytic growth of gold (equivalent to the metal M5) of a few micrometers, in the form of a lattice, to reinforce the rigidity of the membrane, this electrolytic deposition having been carried out on a metallization (type M4).

In summary, the change of state of the membrane (from a high state to a low state) is ensured by the remote electrodes, and it is the dielectric material D1 that withstands the voltage needed to switch the membrane. The dielectric material D2 ensures the performance of the component in the low state and the power withstand. This thus separates the DC part (for actuating the component) from the RF part.

For topographical reasons, it is advantageously possible to choose the thickness of the dielectric material D1 depending on the height of the dielectric material D2. The thickness of the activation electrode with the dielectric material D1 may be equal to the thickness of the RF line under the membrane with the dielectric material D2.

With regard to the (movable) mechanical part of the capacitive RF MEMS switch, the self-supporting membrane is divided into two areas, supported by multiple anchoring points (at least some of which are located at the ground planes for the case of the parallel RF MEMS). The “flexible” areas, as they are referred to, for enabling switching of the membrane from the high state to the low state (FIGS. 8a and 8b), are located at the anchoring points and consist of the metallization M4. The “rigid” area, as it is referred to, consists of the metallization M4, on which a thick metallization M5 (thickness greater than 2 micrometers) is grown by electrodeposition.

This metallization M5 may be structured (for example in the form of a lattice) in order to keep the structure robust and lightweight. The image of one example of electrolytic growth of gold (equivalent to the metal M5) of a few micrometers, in the form of a lattice, to reinforce the rigidity of the membrane (electrolytic deposition carried out on a metallization M4) is illustrated in FIG. 9.

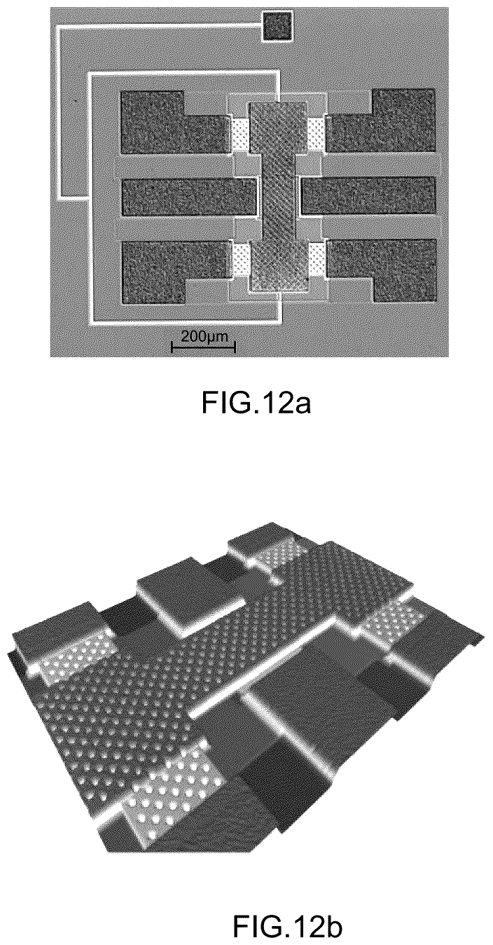

The desired aim is for this area of the membrane to remain planar/rigid, as illustrated in FIG. 10b, which shows the “rigid” area ZR, as it is referred to, FIG. 10a highlighting the “flexible” areas ZF, as they are referred to. The rigid area of the membrane does not deform under the effect of incident power. Deformation of the membrane thus remains allowed only at the anchoring points (flexible areas).

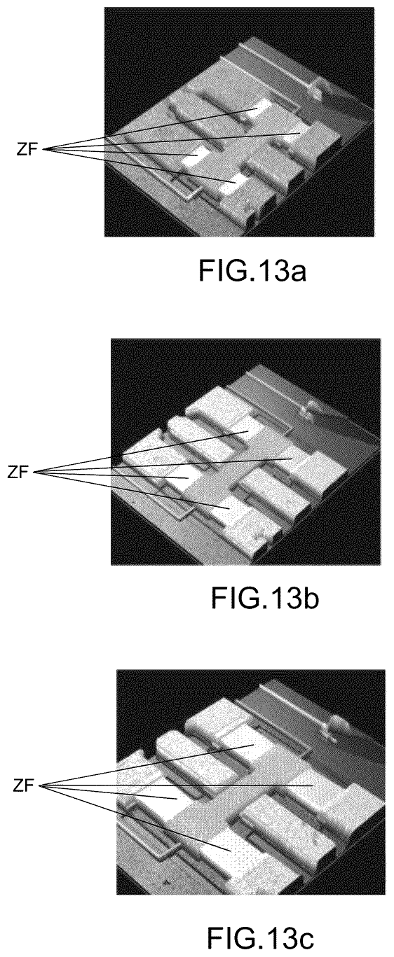

The mechanical properties of the capacitive RF MEMS switch are therefore imparted by the flexible areas of the membrane, which are located at the ground planes. This configuration provides all the flexibility needed to vary the dimensions of the flexible areas in order to adjust the power withstand of the component. For example, reducing the length (F) of the flexible areas (illustrated in FIG. 11) makes them more flexurally rigid, and a larger (DC and RF) voltage will therefore be required to switch the membrane to the low state. While at the same time making the self-supporting structure more flexurally rigid at the anchoring points, it is possible to reduce the DC voltage needed to actuate the component by increasing the dimensions (C and E) of the activation electrodes and the dimensions (C′ and E′) of the parts of the rigid membrane opposite. Multiple advantages are obtained with this methodology:
there are no space constraints for defining the activation electrodes because they are remote from the central transmission line;
it is therefore possible to address high power levels. The electrostatic force, for a given voltage, is proportional to the surface area of the electrodes (Equation 1). The power withstand of the component is defined by the level of flexibility of the flexible areas and the height of the air gap (e_{g});
the control lines may then be outside the device (in contrast to the works by Hao Wei: Hao Wei et al, “High on/off capacitance ratio RF MEMS capacitive switches”, Journal of Micromechanics and Microengineering, 2017), thus limiting their impact on the RF performance of the device when the membrane is in the high state;
the RF architecture is not impacted and RF performance is the same as for a more conventional architecture. Indeed, the changes made are at the ground planes, and will therefore not influence the transmission of the RF signal.

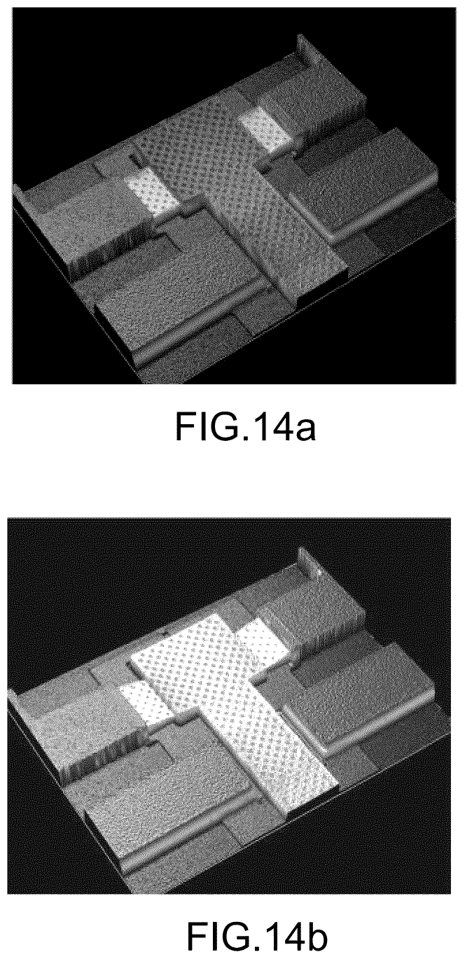

FIGS. 12a and 12b show one example of the architecture of the present invention based on technological steps of microelectronics. FIG. 12a illustrates an optical microscope image of a component according to the invention, and FIG. 12b illustrates a 3D optical profilometer view of a component according to the invention. This component was produced on a high-resistivity silicon substrate with 2 μm of thermal silicon oxide. For this fabrication, the dielectric material D1 is silicon nitride (500 nm) deposited by PECVD, and the dielectric D2 is metal oxide deposited by evaporation. The flexible part of the membrane consists of a multilayer based on refractory material (by sputtering) and Au (by evaporation). The rigid part of this membrane consists of the same multilayer, with an excess thickness of electrolytic Au of a few micrometers.

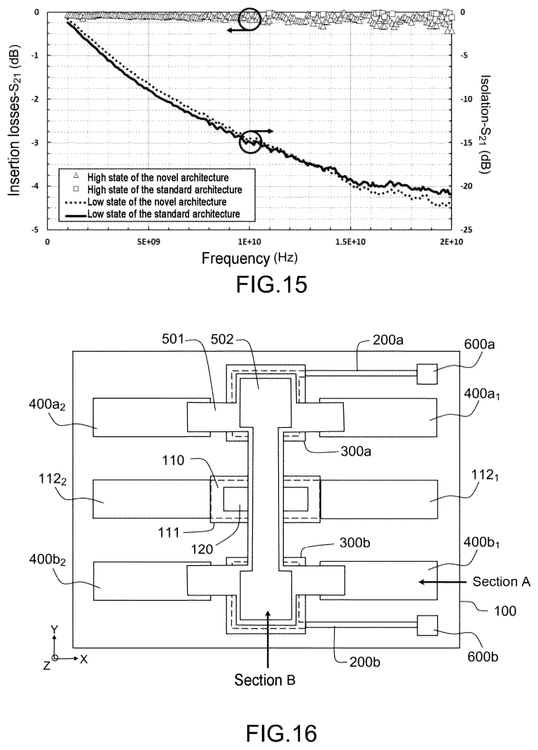

FIGS. 13a, 13b and 13c show optical profilometer acquisitions of 3 capacitive RF MEMS switches based on the principle of the present invention. The three structures that are presented originate from the same fabrication on a high-resistivity silicon substrate with 2 μm of thermal oxide. The length of the flexible areas was varied in order to change the voltage required for actuation from one component to another.

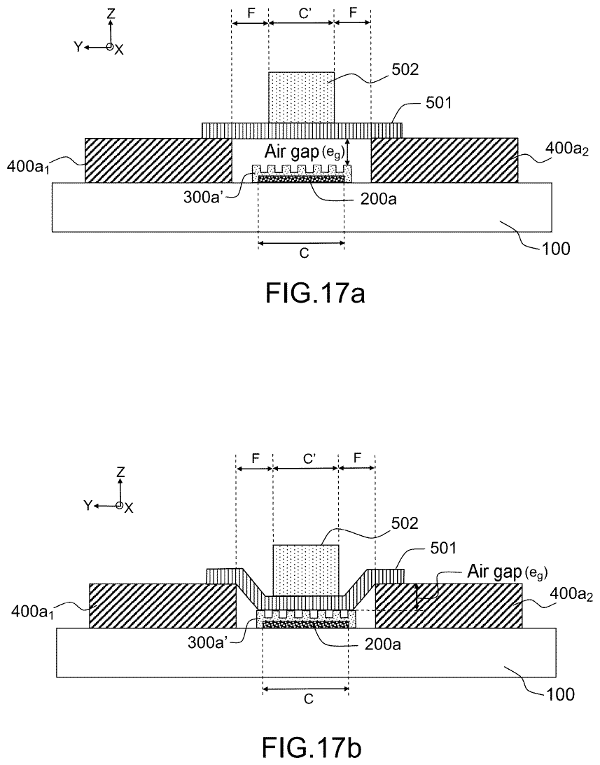

FIGS. 14a and 14b show optical profilometer acquisitions of the switching of an architecture with the shortest flexible areas; FIG. 14a relates to a state in which the membrane is in the high state and FIG. 14b relates to a state in which the membrane is in the low state.

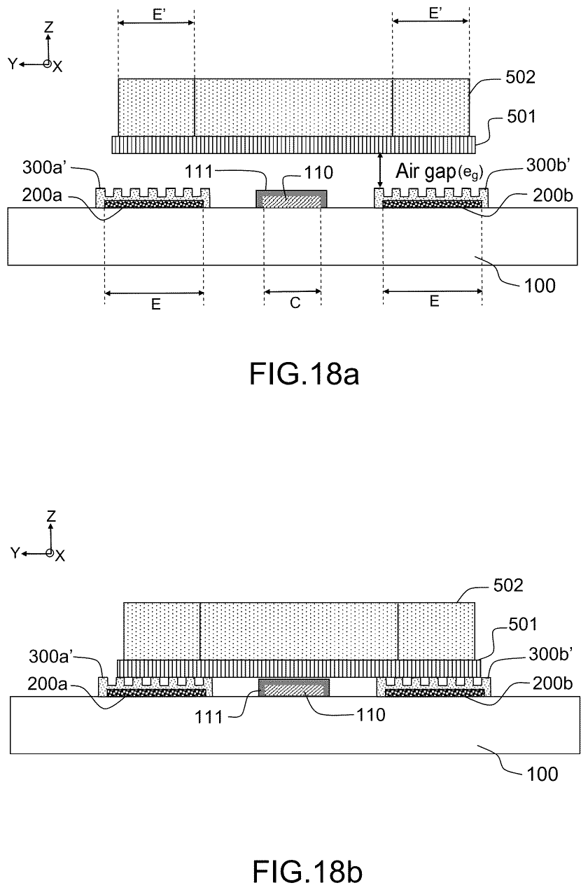

In order to validate this concept, these novel architectures were characterized on an RF bench and their S parameters were compared with those of a standard architecture originating from the same fabrication. FIG. 15 presents these results and shows equivalent S parameters for both types of architecture. Insertion losses are of the order of 0.1 dB at 10 GHz for an isolation of the order of 15 dB for the same frequency.

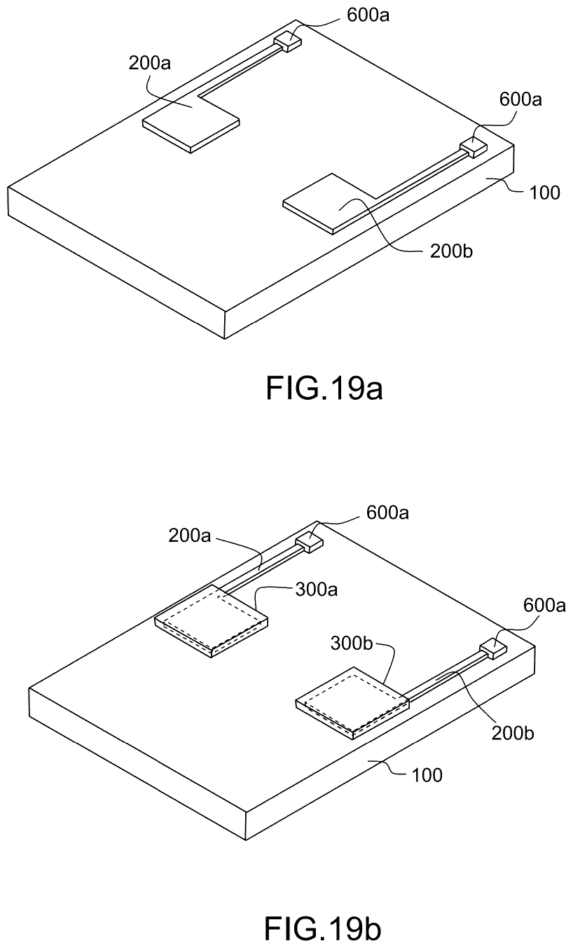

FIG. 16 illustrates a plan view of one example of an architecture according to the invention, showing 2 sectioning axes A and B.

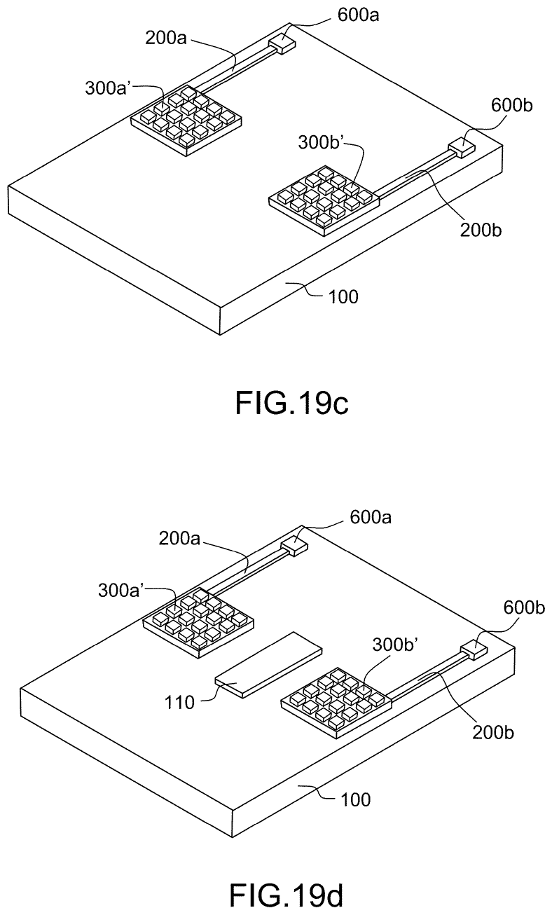

FIGS. 17a and 17b relate to section A and relate, respectively, to the high state and to the low state.

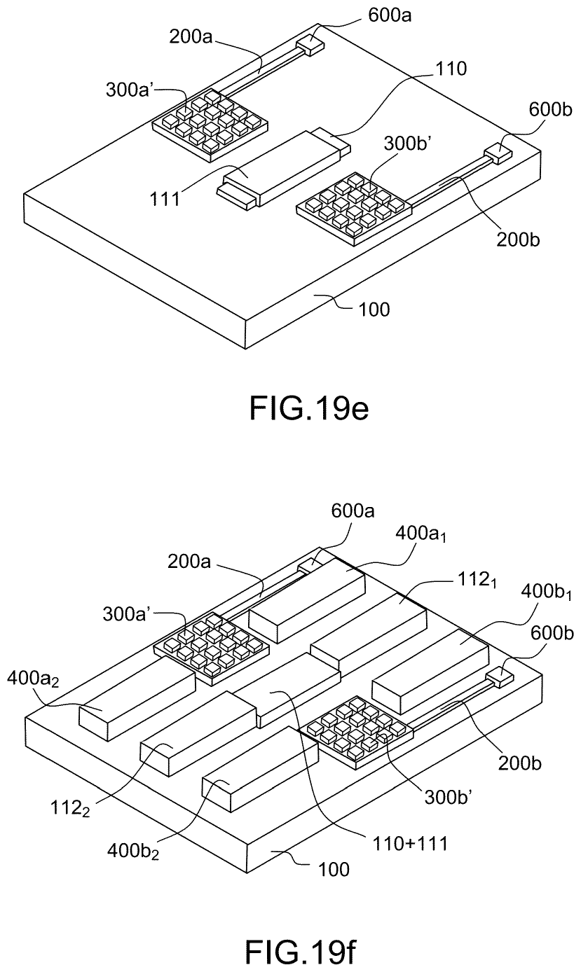

FIGS. 18a and 18b relate to section B and relate, respectively, to the high state and to the low state.

Generally speaking, transferring the activation electrodes to the ground planes makes it possible to manage high power levels while at the same time maintaining moderate actuation voltages and keeping the component compact. The dimensions of the activation electrodes, as well as the dimensions of flexible parts, may be adjusted according to requirements in terms of power level and stress on the actuation voltage. Microstructuring/nanostructuring the dielectric material on the activation electrodes makes it possible to limit the injection of charges into this dielectric and therefore to improve the reliability of the component for an RF power/actuation voltage compared to an unstructured dielectric. DC stress is applied to the dielectric material D1, and the dielectric material D2 is subjected only to RF stress, and therefore the dielectric material D2 may be chosen (thickness and dielectric properties) according to the expected specifications (power withstand and S parameters).

This novel architecture consists of activation electrodes with a thickness of around one hundred nanometers and consisting of a metallization produced by thin film deposition (sputtering, evaporation, etc.). These activation electrodes are located at the ground planes of the component.

The dielectric material D1 above the activation electrodes is chosen for its good voltage withstand, that is to say with a suitable thickness and/or a high dielectric strength. This material may be for example SiO₂, SiN, Al₂O₃, etc. deposited by PECVD, by ALD, by sputtering, etc. for a thickness of around one hundred nanometers that is able to withstand voltages of several hundred volts. This material may be microstructured/nanostructured either by etching or by localized deposition of another dielectric (possibly the dielectric D2) on top. This structuring thus makes it possible to limit the contact surface area when the membrane is in the low state.

The movable membrane consists of a flexible part so as to allow it to move. This flexible part may be based on a metal multilayer deposited by sputtering and/or evaporation. The membrane also consists of a rigid part that may be produced through a thick electrolytic deposition (of around ten micrometers), which may be gold, copper, etc., for example. This growth is carried out on the multilayer used for the flexible part at the areas that it is desired to keep planar under the effect of the injected power. Deformation of the membrane is therefore allowed only in the flexible areas defined by the multilayer. This electrolytic growth may be structured in the form of a lattice in order to minimize the weight of the membrane while at the same time ensuring mechanical rigidity.

The dielectric material D2 is located on the RF line and below the membrane. It may be deposited using various techniques (evaporation, CVD, ALD, etc.) for thicknesses that may range from a few tens of nanometers to a few hundred nanometers. The choice of material and its thickness will be made according to its properties and the desired performance. A floating thin metal layer of a few tens of nanometers may be deposited on the dielectric material in order to optimize the capacitance when the membrane is in the low state. Simple contact of the membrane on this metallization makes it possible to obtain the maximum capacitance while at the same time obviating the quality of contact of the membrane on the RF line (which may be induced by the roughness or the degree of pressing).

The RF line, passing under the membrane, is a metallization with a thickness of a few hundred nanometers that is deposited using a thin film technique (evaporation, sputtering, etc.) and that may be made of gold. Outside the area under the membrane, this RF line may be thickened with an electrolytic deposition that also serves to define the ground planes and the anchors of the flexible parts of the membrane.

The air gap between the activation electrodes and the membrane and between the RF line and the membrane may be from a few hundred nanometers to a few micrometers in height depending on the sought power withstand and the desired switching time. The thickness of the activation electrodes with its dielectric may be adjusted according to the thickness of the RF line with its dielectric so that the air gap is similar between the two contact areas.

### Example of a Method for Producing an Architecture According to the Invention:

### Step 1:

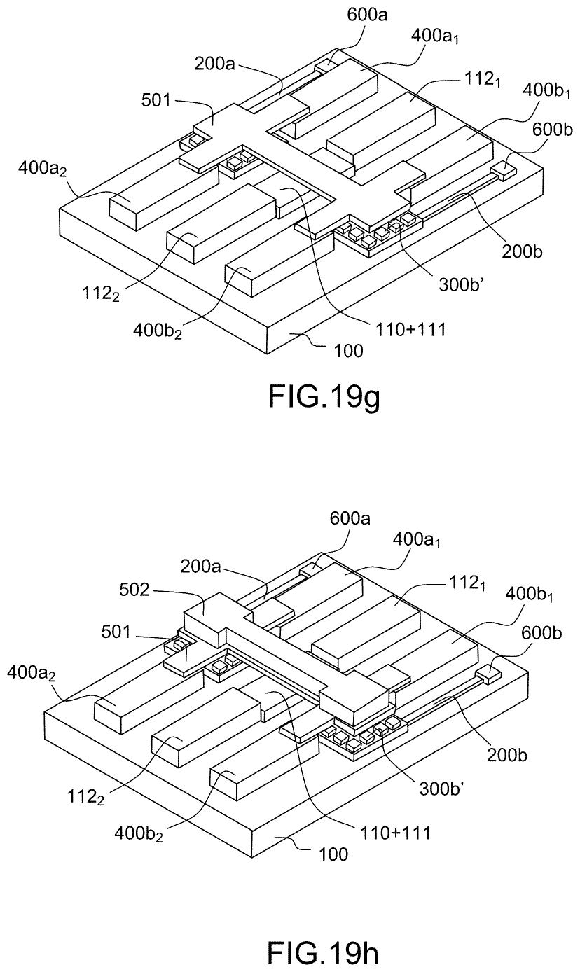

A metallization (metal M2) is deposited, so as to define the activation electrodes 200a and 200b extended by connection pads 600a and 600b, on a substrate 100, as illustrated in FIG. 19a.

### Step 2:

A dielectric material (D1) is deposited on the activation electrodes for the DC performance of the component, as illustrated in FIG. 19b, which shows the dielectric elements 300a and 300b above the electrodes 200a and 200b.

### Step 3:

An operation of microstructuring/nanostructuring the dielectric above the activation electrodes is carried out so as to define the microstructured/nanostructured elements 300a′ and 300b′ above the elements 200a and 200b, as illustrated in FIG. 19c.

### Step 4:

A metallization (metal M1) is deposited in order to define the RF line 110 intended to pass under the membrane, as illustrated in FIG. 19d.

### Step 5:

The dielectric D2 is deposited on the RF line for the RF performance of the component, defining a dielectric element 111 above the line 110, as illustrated in FIG. 19e.

### Step 6:

A first electrolytic growth operation (metal M3) is carried out so as to thicken the RF line with elements 112₁ and 112₂ outside the area in which the membrane is to be lowered and also so as to define ground planes 400a1, 400b₁, 400a₂ and 400b₂, as illustrated in FIG. 19f.

### Step 7:

The lower element 501 of the membrane is produced. For this purpose, the metallization (metal M4) is deposited and subjected to a structuring operation, defining the geometry of the membrane and the flexible parts of the membrane 501, as illustrated in FIG. 19g.

### Step 8:

The upper element 502 of the membrane is produced. For this purpose, lastly, a localized electrolytic deposition operation (metal M5) is carried out on top of the metallization M4 in order to define the rigid areas of the membrane, as illustrated in FIG. 19h.

The architecture of the capacitive shunt RF MEMS switch described above may be adapted to an ohmic contact, a metal contact between the membrane and the RF line, without changing anything regarding the mechanical nature of the membrane or the way it is activated. The architecture differs in that there will be no dielectric above the RF line when it passes under the membrane and that contact will be made directly between the RF line and the membrane when the latter is in the low state.

Similarly, the architecture of the capacitive shunt RF MEMS switch described above may be adapted to a microstrip line rather than a coplanar one. The architecture differs in that the ground plane is not located on either side of the central signal line, but on the rear face of the fabrication substrate, and that metallized vias, holes in the substrate connecting the front face to the rear face and lined/filled with a conductive material for thus electrically connecting the two faces, electrically connect the membrane to the ground plane on the rear face.

Similarly, the architecture of the capacitive shunt RF MEMS switch described above may be adapted to a series architecture of the RF MEMS switch. The architecture differs in that the RF line is discontinuous and the membrane is not connected to the ground plane; it is suspended above the first part of the RF line and is connected to the second part of the RF line. When the membrane is in the low state, the two portions of the RF line are connected, allowing the RF signal to pass.

The combination of these features makes it possible to produce the following eight types of structure: capacitive coplanar shunt RF MEMS, capacitive coplanar series RF MEMS, ohmic coplanar shunt RF MEMS, ohmic coplanar series RF MEMS, capacitive microstrip shunt RF MEMS, capacitive microstrip series RF MEMS, ohmic microstrip shunt RF MEMS, ohmic microstrip series RF MEMS.

1. A capacitive radiofrequency microelectromechanical system comprising a metal membrane suspended above an RF transmission line arranged along a first axis X on the surface of a substrate, activation electrodes and ground planes on which said membrane rests, said metal membrane comprising:
a lower element having a first part located partially above said electrodes, which are covered by elements comprising at least one first dielectric material (D1), and partially above said RF line, which is covered by an element made of a second dielectric material (D2), said lower element having second parts located partially in contact with said ground planes;
an upper element located above said first part of the lower element;
the activation electrodes being arranged on either side of the RF transmission line;
said ground planes being arranged on either side of the RF line and along axes parallel to said first axis X;
said membrane comprising flexible areas (ZF) consisting of some of the second parts of the lower element and a rigid area (ZR) consisting of the stack of the first part of the lower element and the upper element.

2. The capacitive radiofrequency microelectromechanical system as claimed in claim 1, wherein said elements comprising at least one first dielectric material (D1) are structured and have structuring patterns, of dimensions between 50 nanometers and 5 micrometers.

3. The capacitive radiofrequency microelectromechanical system as claimed in claim 1, wherein the first dielectric material (D1) has a strength greater than or equal to 5 MV/cm, and is for example made of SiO₂ or SiN or Al₂O₃.

4. The capacitive radiofrequency microelectromechanical system as claimed in claim 1, wherein the element made of a second dielectric material (D2) is covered with an upper metal element.

5. The capacitive radiofrequency microelectromechanical system as claimed in claim 1, wherein the total thickness of an activation electrode and of an element made of a first dielectric material is equal to the total thickness of the thickness of the part of said RF line under the membrane and of an element made of a second dielectric material.

6. The capacitive radiofrequency microelectromechanical system as claimed in claim 1, wherein the thickness of the lower element of the membrane is between 500 nanometers and 2 micrometers.

7. The capacitive radiofrequency microelectromechanical system as claimed in claim 1, wherein the thickness of the upper element of said membrane is greater than 2 micrometers.

8. The capacitive radiofrequency microelectromechanical system as claimed in claim 1, wherein the upper element of said membrane is structured, said structure being for example in the form of a lattice and having patterns of dimensions greater than one micrometer.

9. The capacitive radiofrequency microelectromechanical system as claimed in claim 1, wherein the second dielectric material has a dielectric constant ε₀ greater than that of silicon oxide, said second dielectric material being for example HfO₂ or ZrO₂ or Y₂O₃ or Al₂O₃ or SiN.

10. The capacitive radiofrequency microelectromechanical system as claimed in claim 1, wherein the lower element of the membrane is made of multilayers based on one or more refractory materials, for example W, Mo, Ta, TaN, TiN, TiW and one or more conductive materials, for example Au, Al, Cu, the upper element of the membrane being made of conductive material, for example Au or Cu.

11. A method for fabricating a capacitive radiofrequency microelectromechanical system as claimed in claim 1, comprising:
a step of producing activation electrodes on the surface of a substrate;
a step of producing elements made of at least one first dielectric material (D1) on the surface of some of said activation electrodes;
a step of producing the RF line located between said activation electrodes;
a step of producing an element made of a second dielectric material (D2) above part of the RF line;
a step of producing said ground planes on either side of said RF line;
a step of producing the lower element of said membrane;
a step of producing the upper element of said membrane.

12. The method for fabricating a capacitive radiofrequency microelectromechanical system as claimed in claim 11, wherein the step of producing the activation electrodes on the surface of a substrate is carried out by sputtering or by evaporation.

13. The method for fabricating a capacitive radiofrequency microelectromechanical system as claimed in claim 11, wherein the lower element of the membrane is produced by multilayer depositions comprising at least one metal layer made of Au or Al or Cu and at least one other metal layer, for example made of refractory material, said depositions being carried out by sputtering and/or evaporation.

14. The method for fabricating a capacitive radiofrequency microelectromechanical system as claimed in claim 11, wherein the upper element of said membrane is produced by electrolytic deposition.

15. The method for fabricating a capacitive radiofrequency microelectromechanical system as claimed in claim 11, wherein the element made of a second dielectric material on the surface of said RF line is produced by physical vapor deposition (PVD) or by chemical vapor deposition (CVD) or by atomic layer deposition (ALD) of atomic thin films with thicknesses for example between 20 nanometers and 300 nanometers.

16. The method for fabricating a radiofrequency microelectromechanical system as claimed in claim 11, comprising carrying out a step of partially thickening said RF line in regions located at the periphery of said membrane.

17. The method for fabricating a radiofrequency microelectromechanical system as claimed in claim 16, wherein the step of partially thickening said RF line and the step of producing said ground planes are carried out in one and the same metal deposition step.

18. The method for fabricating a radiofrequency microelectromechanical system as claimed in claim 17, wherein the production of the ground planes or the production of the ground planes and the step of partially thickening said RF line are carried out by electrolytic growth.

19. The method for fabricating a radiofrequency microelectromechanical system as claimed in claim 11, wherein the structuring patterns of said elements made of at least one first dielectric material (D1) and present above said electrodes are produced by etching a first dielectric material (D1) or by localized deposition of a dielectric material on a first dielectric material (D1).
